(19) United States
(12) Patent Application Publication
(10) Pub. No.: US 2007/0075396 A1
(43) Pub. Date: Apr. 5, 2007

(54) Semiconductor device and manufacturing method thereof

(75) Inventor: Atsushi Ogishima, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC.

(21) Appl. No.: 11/529,466

(22) Filed: Sep. 29, 2006

(30) Foreign Application Priority Data
Sep. 30, 2005 (JP) 2005-286871

(51) Int. Cl. H01L 21/82

(52) U.S. Cl. 257/529; 438/132

(57) ABSTRACT

A semiconductor device includes a semiconductor substrate having a diffusion layer. An insulating film is formed on the semiconductor substrate, a fuse section of fuses is formed on the insulating film. An interlayer insulating film is formed on the fuse section and the insulating film, and an antenna section is formed on the interlayer insulating film in correspondence to the fuse section.

### BACKGROUND OF THE INVENTION

1. Field of the Invention

The present invention relates to a semiconductor device having a redundancy function of replacing a defective bit with a redundant bit by cutting a fuse and a conductive antenna section, and a method of manufacturing the same.

2. Description of the Background Art

FIG. 1 is a plan view schematically showing the structure of a fuse region in a conventional semiconductor device having a redundancy function of replacing a defective bit with a redundant bit by cutting a fuse. As shown in FIG. 1, in the conventional semiconductor device, a fuse window 12 is formed for the cutting margin of a fuse by removing a portion of protection film which is laminated on a fuse section 10. Then, each of fuses of the fuse section 10 is connected to a redundancy control circuit 14 through a connecting layer 11. FIGS. 2A to 2C show cross sectional views showing a portion of the semiconductor device corresponding to an uncut fuse of the fuse section 10 along the line A-A′ in FIG. 1, and FIGS. 3A to 3C show cross sectional views showing a portion of the semiconductor device corresponding to a cut fuse of the fuse section 10 along the line B-B′ in FIG. 1.

FIGS. 2A to 2C show cross sectional views a memory cell region (FIG. 2A), a peripheral circuit region (FIG. 2B), and fuse section of a redundancy circuit region (FIG. 2C), respectively, which are all formed on a same substrate. The memory cell region (FIG. 2A) and the peripheral circuit region (FIG. 2B) are shown for the redundancy circuit region (FIG. 2C). Hereinafter, a description will be given on the configuration of a semiconductor device including the redundancy circuit (FIG. 2C) with a redundancy function. In the redundancy circuit, groove-type separation regions 107 and diffusion layer regions 106 are formed in a silicon substrate. The diffusion layer regions 106 on both sides of the groove-type separation region 107 are the connecting layers 11 in FIG. 1, and gate electrodes 108 and the diffusion layer regions 106 on the outer sides of the gate electrodes 108 correspond to the redundancy control circuit 14 in FIG. 1. For example, a bit line 110 of tungsten in the memory cell region is used as a first wiring layer 110 in the peripheral circuit and the redundancy circuit, and is connected to the diffusion layer regions 106 through plugs 109. A storage capacitor is composed of a lower electrode 111, an insulating film 112, and an upper electrode 113, and is connected to the diffusion layer 106 through a plug 105. A second wiring layer 115 is formed of aluminum and connected to the first wiring layer 110 through a plug 114. A third wiring layer 117 is formed of aluminum and connected to the second wiring layer 115 through a plug 116. A protection film of a nitride film 118 and a polyimide film 119 is formed on the second wiring layer. In the redundancy circuit shown in FIG. 2C, a fuse 132 is formed in the same layer as the second wiring layer 115, and is connected to a diffusion layer regions 106 through the plugs 114, the first wirings 110, and the plugs 109. On the other hand, the fuse 132 shown in FIG. 3C is cut with a laser beam, and an insulating film 120 on the fuse 132 is vaporized with heat generated upon laser irradiation, thereby forming a fuse exposing section 133. Thus, the cut section of the fuse 132 is partially exposed to the outside.

Now, FIG. 4 shows a general manufacturing process of the conventional semiconductor device. The manufacturing process of the conventional semiconductor device includes a laser trimming (step S01) after formation of wiring layers on or above a semiconductor substrate, formation of a protection film, and formation of an opening in the protection film; a probe test (step S02); a back grinding (step S03); a dicing (step S04); a die bonding (step S05); a wire bonding (step S06); and a resin molding (step S07). As shown in FIG. 4, a state in which the cut section of the fuse 132 is partially exposed continues from the laser trimming (step S01) to the end of the resin molding (step S07). FIGS. 5A to 5C show states that the protection film 118 and 119 covering the chip surface is charged, in the process from the laser trimming (step S01) to the resin molding (step S07) shown in FIG. 4. In the redundancy circuit shown in FIG. 5C, charged particles or electrons 134 adhered onto the protection film nay enter the cut section of the fuse 132 and be discharged to the gate electrode 108 through the diffusion layer 106 as shown by a path 135. As a result, an internal circuit is sometimes broken down. This causes malfunction or breakdown in the redundancy control circuit.

Japanese Laid Open Patent Publication (JP-a-Heisei 11-17016) discloses “Semiconductor Integrated Circuit Device and Manufacturing Method Thereof”. In this conventional example, the semiconductor integrated circuit device is provided with a redundancy circuit which has a redundant bit and in which a fuse is cut to replace a defective bit with the redundant bit. A fuse section is composed of a first fuse that is cut after a final passivation film formation and a second fuse that is cut before the final passivation film formation. In this structure, since a protection film on the fuse is removed, a guard ring is formed for the purpose of mainly ensuring the humidity resistance and prevention of contamination from the outside. This guide ring is formed to (1) surround the fuse seamlessly, and (2) in a floating state without connection to the substrate in particular.

Japanese Laid Open Patent Application (JP-P2000-156412A) discloses “Semiconductor Device and Manufacturing Method Thereof”. In this conventional example, the semiconductor device includes a fuse provided on a semiconductor substrate; a plurality of insulating films formed on the fuse; and a fuse cut window which is provided as an opening of the insulating film. The semiconductor device has a flat inner bottom surface. A metal film provided for a side surface of the fuse cut window is not required to be connected to the substrate and does not have a purpose of discharge of charged particles.

As described above, although there are conductive films such as a guard ring in neighborhood of the fuse cut window, the first and second examples do not have a purpose of the discharge of the charged particles.

In conjunction with the above description, a fuse section of a semiconductor device is disclosed in Japanese Laid Open Patent Application (JP-P2001-189385 A). The semiconductor device includes a fuse line, a first interlayer insulating film formed on the fuse line, and a second interlayer insulating film formed on the first interlayer insulating film and having a fuse opening section in which the first interlayer insulating film is exposed. A passivation film is formed as a unit, over a top layer of the semiconductor device, the second interlayer insulating film and side walls of the of the fuse opening section, and has a function as a protection film which blocks off invasion of moisture through the side walls.

Also, a semiconductor device is disclosed in Japanese Laid Open Patent Application (JP-P2000-156412A). In this conventional semiconductor device, a contact is formed to be connected with a diffusion region of a MOS transistor of a peripheral circuit after a second interlayer insulating film of silicon oxide film. A first metal film is formed and patterned into a requested shape, resulting in a first metal wiring line. At this time, the first metal wiring line is exposed along the circumference of a fuse cutting window. A second metal film is formed in the peripheral circuit and patterned into a desired shape. Thus, a second metal wiring line is formed, including a pad electrode connected with the first metal wiring line. The second metal film is formed around the fuse cutting window.

Also, a semiconductor device is disclosed in Japanese Laid Open Patent Application (JP-A-Heisei 11-145291). In the semiconductor device of this conventional example, a fuse is formed on a semiconductor substrate. An insulating film is formed on first to third regions. The insulating film has a first thickness in the first region where there is the fuse, a second thickness in the second region around the first region, and a third thickness in the third region around the second region. A cover film is formed on the second and third regions.

Also, a semiconductor integrated circuit apparatus is disclosed in Japanese Laid Open Patent Application (JP-A-Heisei 11-17016). A fuse has a guard ring which is composed of a set of a wiring M3 around a fuse element, a wiring M2 and a contact connecting the wirings M3 and M2, and a set of the wiring M2, a wiring M1 and a contact. The guard ring is connected to a semiconductor region of a ground voltage through the contacts.

Also, a semiconductor device is disclosed in Japanese Laid Open Patent Application (JP-A-Heisei 9-69571). In the conventional semiconductor device, a first interlayer insulating film is formed to cover a fuse element. A second interlayer insulating film is formed on the first interlayer insulating film and has an opening for the fuse element. The surface of the second interlayer insulating film around the opening and side walls of the opening are covered with a metal layer or a metal layer and passivation layer.

### SUMMARY OF THE INVENTION

An object of the present invention is to provide a semiconductor device which has a redundant function of replacing a defective bit with a redundant bit so that it is superior in charging resistance and has high reliability, and a method of manufacturing the same.

Also, another object of the present invention is to provide a semiconductor device which has an antenna section which is at least partially exposed in a fuse window and a method of manufacturing the same.

In an aspect of the present invention, a semiconductor device includes a semiconductor substrate having a diffusion layer; an insulating film formed on the semiconductor substrate; a fuse section of fuses formed on the insulating film; an interlayer insulating film formed on the fuse section and the insulating film; and an antenna section formed on the interlayer insulating film in correspondence to the fuse section.

Here, the semiconductor device may further include a contact plug configured to connect the antenna section and the diffusion layer. The semiconductor device may further include a protection layer formed on the antenna section and the interlayer insulating film; and a fuse window formed by removing a portion of the protection layer in correspondence to the fuse section to allow a fuse to be cut. The antenna section may be arranged such that at least a portion of the antenna section is exposed in the fuse window.

Also, the antenna section may have two sections. One of the two sections may be arranged along one end of each of fuses of the fuse section, and the other may be arranged along the other end of each fuse. Otherwise, the antenna section may have a ring shape to surround the fuse section.

The fuse window may be formed such that at least a port of the antenna section is exposed. Otherwise, the fuse window may be formed such that a whole of the antenna section is exposed.

In another aspect of the present invention, a semiconductor memory device include a semiconductor substrate having a diffusion layer of diffusion regions; a memory cell region formed on the semiconductor substrate; a device region formed on the semiconductor substrate; and an input/output circuit region formed on the semiconductor substrate to input and output data. The device region includes an insulating film formed directly or indirectly on the semiconductor substrate; a fuse section of fuses formed on the insulating film; an interlayer insulating film formed on the fuse section and the insulating film; an antenna section formed in the interlayer insulating film in correspondence to the fuse section; and a contact connected to the antenna section and the diffusion layer.

In still another aspect of the present invention, a method of manufacturing a semiconductor device is achieved by forming an insulating film above the semiconductor substrate;

forming a fuse section having fuses on the insulating film;

forming an interlayer insulating film on the fuse section and the insulating film; and

forming an antenna section on the interlayer insulating film in correspondence to the fuse section.

The antenna section may have two sections. In this case, the forming an antenna section may be achieved by forming one of the two sections along one end of each of the fuses of the fuse section, and the other along the other end of each fuse. Otherwise, the forming an antenna section may be achieved by forming the antenna section of a ring shape to surround the fuse section.

Also, the method may be achieved by further forming a protection layer on the antenna section and the interlayer insulating film.

Also, the method may be achieved by further forming a fuse window by removing a portion of the protection layer such that at least a portion of the antenna section is exposed; and by removing at least a portion of the interlayer insulating film such that at least a portion of the fuses is exposed.

Also, the removing a portion of the protection layer may be achieved by removing the interlayer insulating film such that a whole of the antenna section is exposed.

### BRIEF DESCRIPTION OF THE DRAWINGS

FIG. 1 is a plan view schematically showing the configuration of a fuse region in a conventional semiconductor device with a fuse section;

FIG. 2A is a diagram showing an uncut fuse section (A-A′) of FIG. 1;

FIG. 2B is a diagram showing an uncut fuse section (A-A′) of FIG. 1;

FIG. 2C is a diagram showing an uncut fuse section (A-A′) of FIG. 1;

FIG. 3A is a diagram showing a cut fuse section (B-B′) of FIG. 1;

FIG. 3B is a diagram showing a cut fuse section (B-B′) of FIG. 1;

FIG. 3C is a diagram showing a cut fuse section (B-B′) of FIG. 1;

FIG. 4 is a diagram showing manufacturing processes of the conventional semiconductor device;

FIG. 5A is a diagram showing the state of the surface with charges generated thereon by charging in FIG. 3A;

FIG. 5B is a diagram showing the state of the surface with charges generated thereon by charging in FIG. 3B;

FIG. 5C is a diagram showing the state of the surface with charges generated thereon by charging in FIG. 3C;

FIG. 6 is a block diagram showing the configuration of a semiconductor memory including a semiconductor device as a redundancy circuit according to embodiments of the present invention;

FIG. 7 is a top view showing the schematic configuration of a fuse region in the semiconductor device according to a first embodiment of the present invention;

FIG. 8A is a diagram showing a cut fuse section (C-C′) of FIG. 7;

FIG. 8B is a diagram showing a cut fuse section (C-C′) of FIG. 7;

FIG. 8C is a diagram showing a cut fuse section (C-C′) of FIG. 7;

FIG. 9A is a diagram showing a section (D-D′) of FIG. 7;

FIG. 9B is a diagram showing a section (D-D′) of FIG. 7:

FIG. 9C is a diagram showing a section (D-D′) of FIG. 7;

FIG. 10A is a diagram showing the state of the surface with charges generated thereon by charging in FIG. 9A;

FIG. 10B is a diagram showing the state of the surface with charges generated thereon by charging in FIG. 9B;

FIG. 10C is a diagram showing the state of the surface with charges generated thereon by charging in FIG. 9C;

FIG. 11 is a diagram showing manufacturing processes of the semiconductor devise according to the first embodiment of the present invention;

FIG. 12 is a diagram showing, of the manufacturing processes of the semiconductor device according to the first embodiment, the process of forming a first wiring layer;

FIG. 13 is a diagram showing, of the manufacturing processes of the semiconductor device according to the first embodiment, the process of forming a second wiring layer;

FIG. 14 is a diagram showing, of the manufacturing processes of the semiconductor device according to the first embodiment, the process of forming a third wiring layer;

FIG. 15 is a diagram showing, of the manufacturing processes of the semiconductor device according to the first embodiment, the process of forming a protection film layer;

FIG. 16 is a diagram showing, of the manufacturing processes of the semiconductor device according to the first embodiment, the process of opening the protection film layer;

FIG. 17 is a diagram showing, of the manufacturing processes of the semiconductor device according to the first embodiment, the processes from laser trimming to a wire bonding;

FIG. 18 is a top view showing the schematic configuration of a fuse region in the semiconductor device according to a second embodiment of the present invention;

FIG. 19 is a top view showing the schematic configuration of a fuse region in the semiconductor device according to a third embodiment of the present invention; and

FIG. 20 is a top view showing the schematic configuration of a fuse region in the semiconductor device according to a fourth embodiment of the present invention.

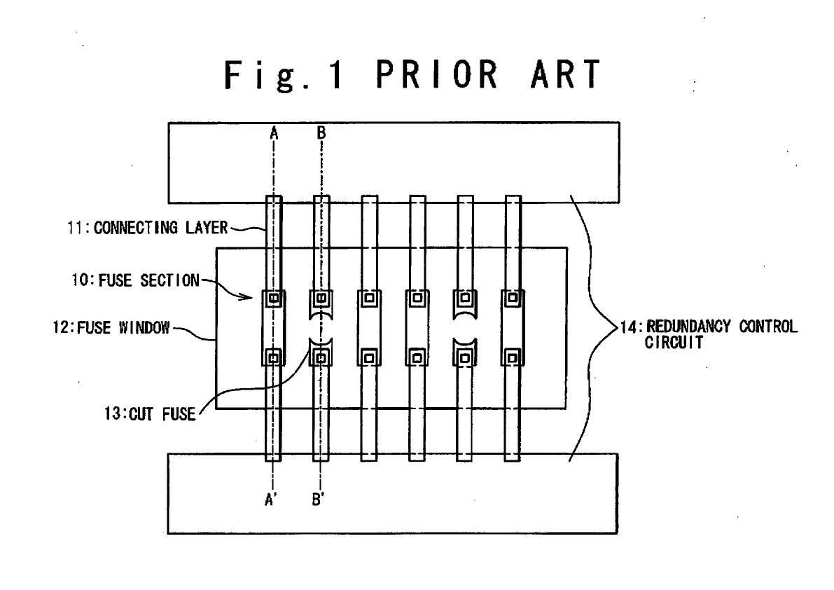

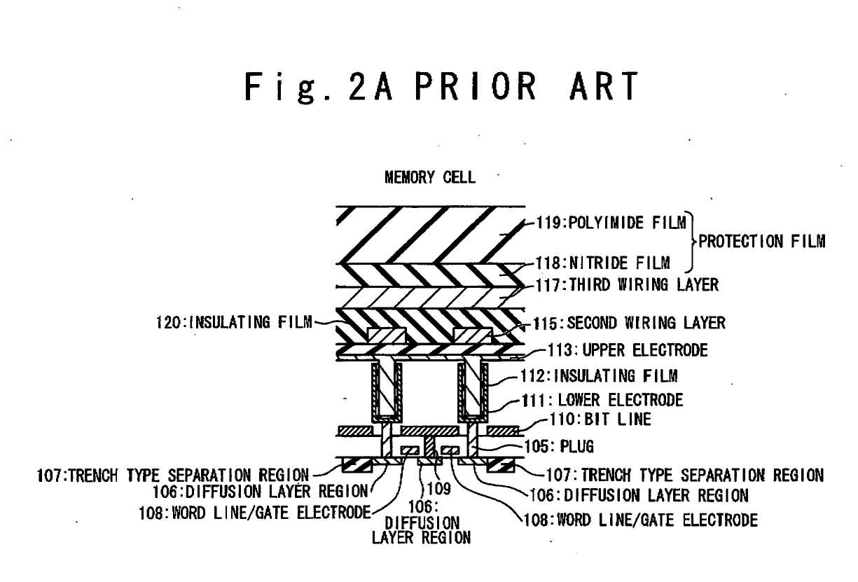

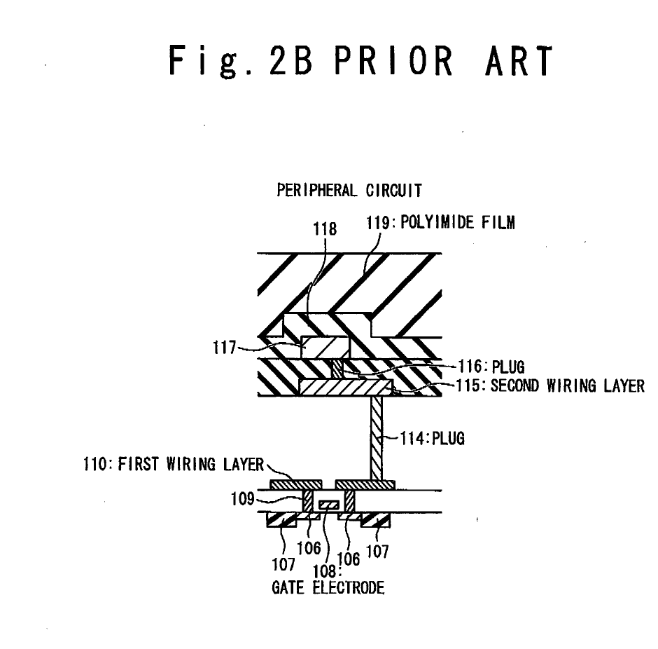

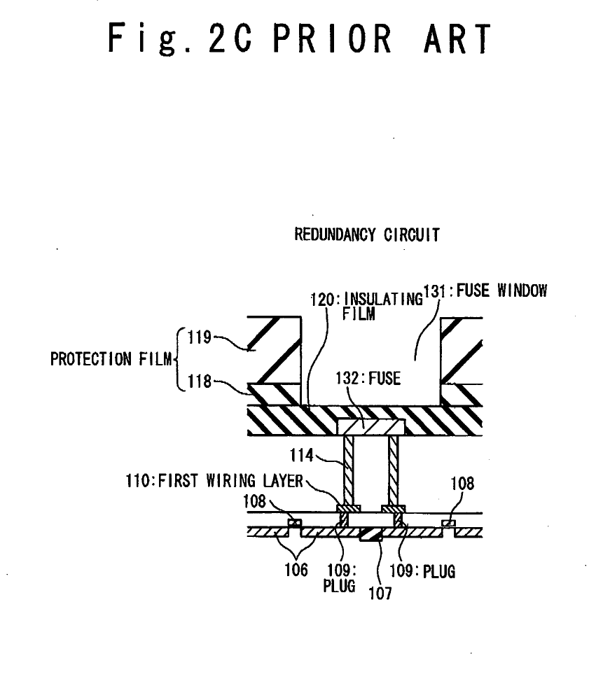

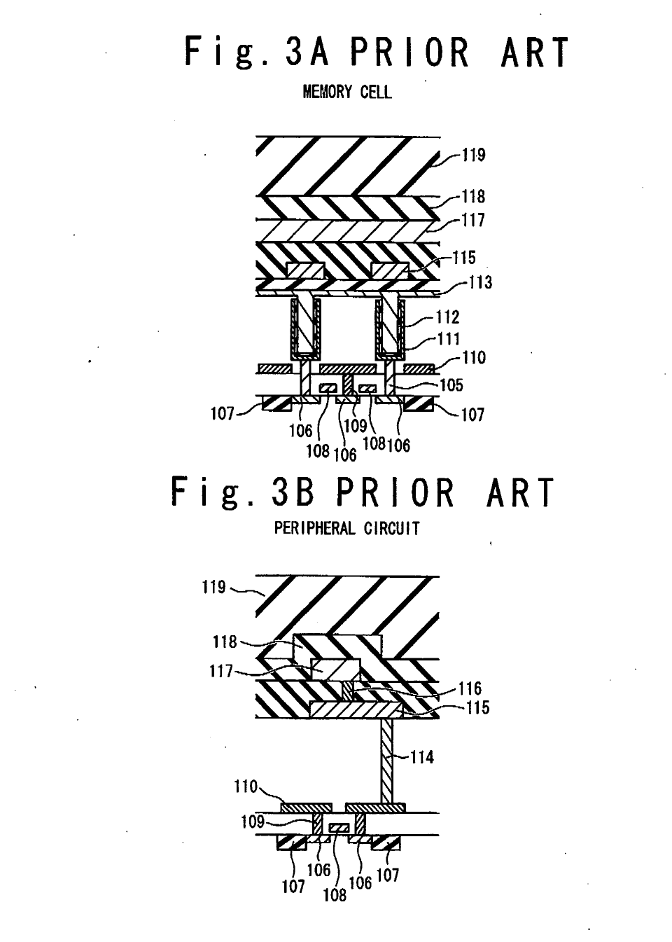

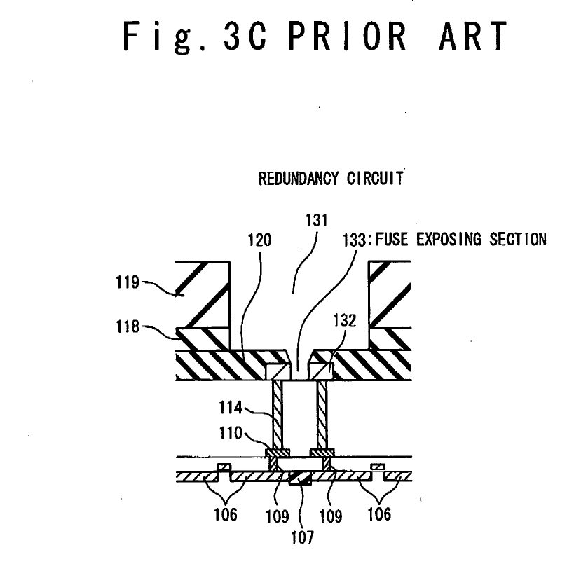

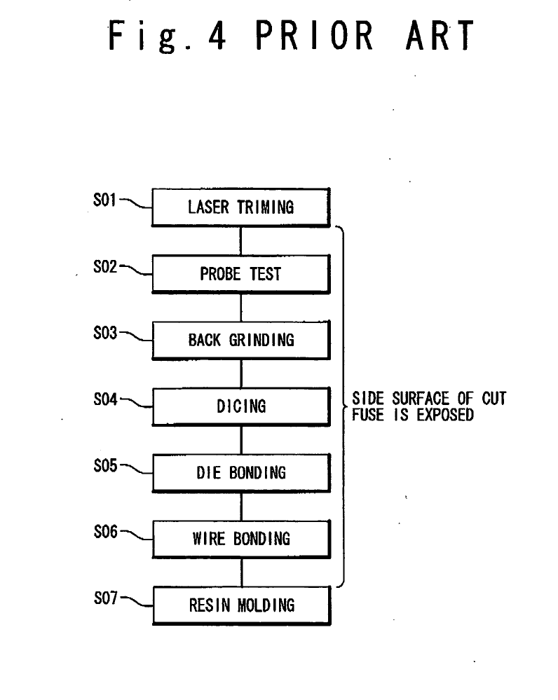

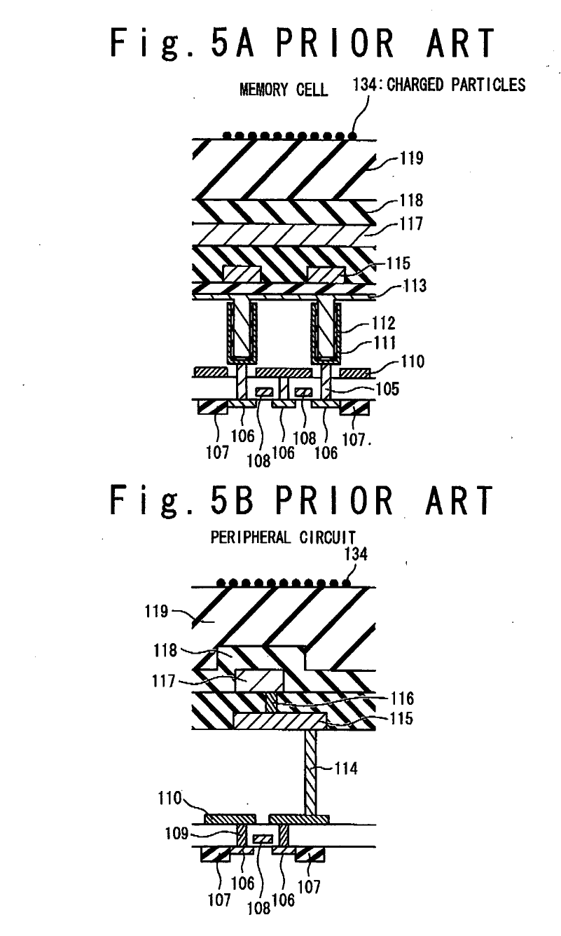

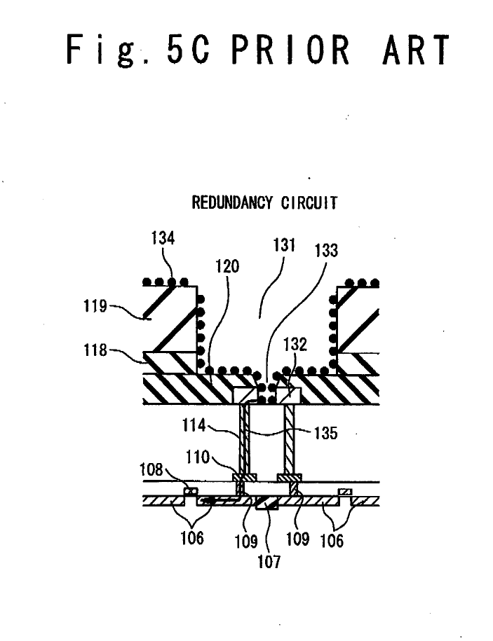

### DESCRIPTION OF THE PREFERRED EMBODIMENTS

Hereinafter, a semiconductor device having a fuse section such as a DRAM (dynamic random access memory) and a method of manufacturing the same, according to the present invention will be described with reference to the attached drawings.

In the semiconductor device of the present invention, a fuse is cut to replace a defective bit with a redundant bit. The semiconductor device of the present invention includes a semiconductor substrate in which diffusion layers are formed; a plurality of wiring layers formed above the diffusion layers through interlayer insulating films; and a protection film formed on the above-mentioned wiring layers. In addition, the semiconductor device has plugs for electrically connecting between the adjacent two layers of the plurality of wiring layers and between the bottom wiring layer of the plurality of wiring layers and the diffusion layer mentioned above. In the semiconductor device of the present invention, a fuse layer is formed above the semiconductor substrate through an insulating film such as an interlayer insulating film. The fuse layer is formed in the wiring layer below the top wiring layer by one layer. To permit the fuse layer to be cut in order to replace the defective bit with the redundant bit, a fuse window is formed by removing the protection film laminated on the fuse layer. The semiconductor device of the present invention includes, in particular, an antenna section 15 is formed in the top wiring layer formed above the fuse layer through an interlayer insulating film. The antenna section is formed to be partially exposed in the fuse window. As a result, the surface portion of the semiconductor device is charged due to moisture or the like. Thus, when charged particles or electrons adhere onto the surface, the charged particles conventionally pass through the fuse section exposed in the fuse window to a gate electrode and then break down an internal circuit. However, in the present invention, the charged particles are led to the antenna section formed in an upper layer than the fuse section before passing to the gate electrode. The charged particles or electrons are then discharged into the substrate from the diffusion layers formed in the substrate surface through the antenna section. In the semiconductor device of the present invention, as mentioned above, it can be prevented that the charged particles or electrons adhering onto the surface pass through the fuse section and then enter a route that breaks down the internal circuit.

### First Embodiment

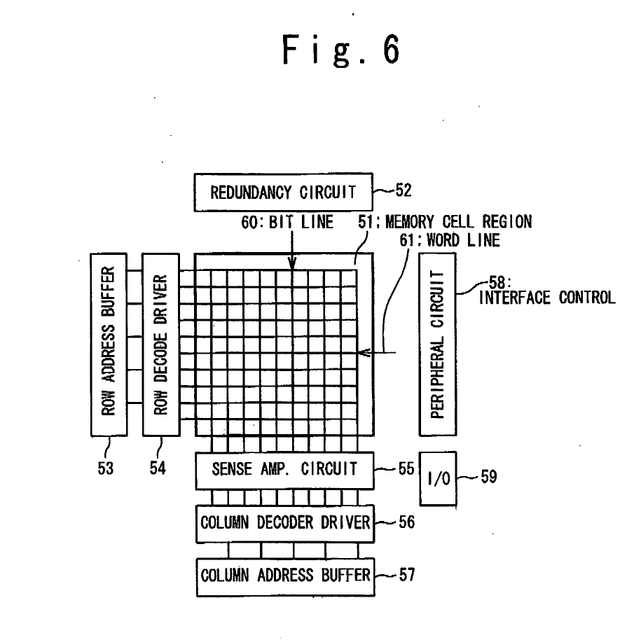

FIG. 6 is a block diagram showing the configuration of a DRAM (dynamic random access memory) as a semiconductor device having a fuse section according to a first embodiment of the present invention. The semiconductor memory is provided with a memory cell region 51, a redundancy circuit 52 for performing redundancy control of the memory cell region 51, a peripheral circuit 58, and an I/O 59. The redundancy circuit 52 and the memory cell region 51 are formed on a same chip at least. In the memory cell region 51, a row decoder driver 54 and a row address buffer 53 are serially connected to word lines 61. A sense amplifier circuit 55, a column decoder driver 56, and a column address buffer 57 are serially connected to bit lines in the memory cell region 51.

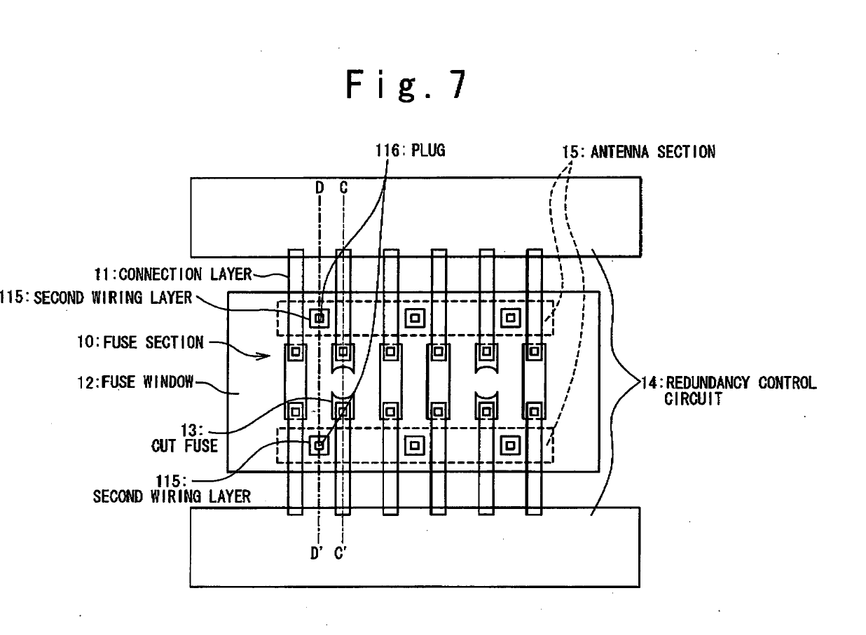

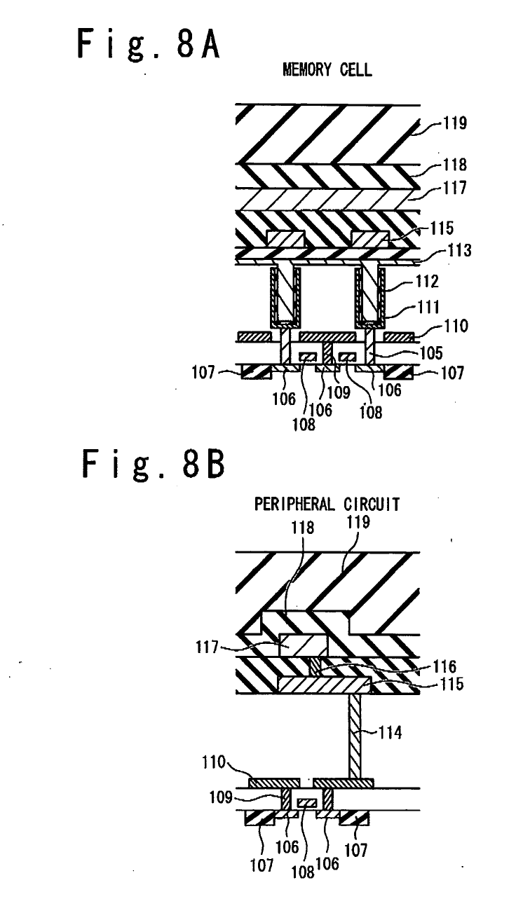

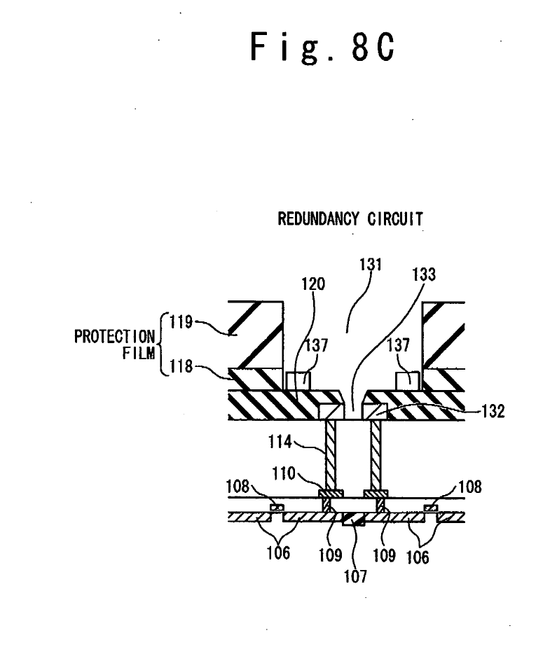

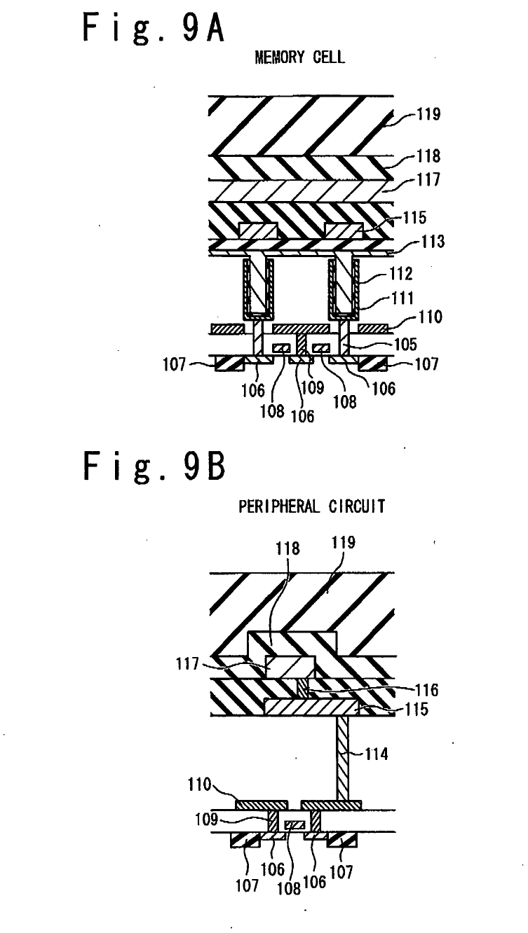

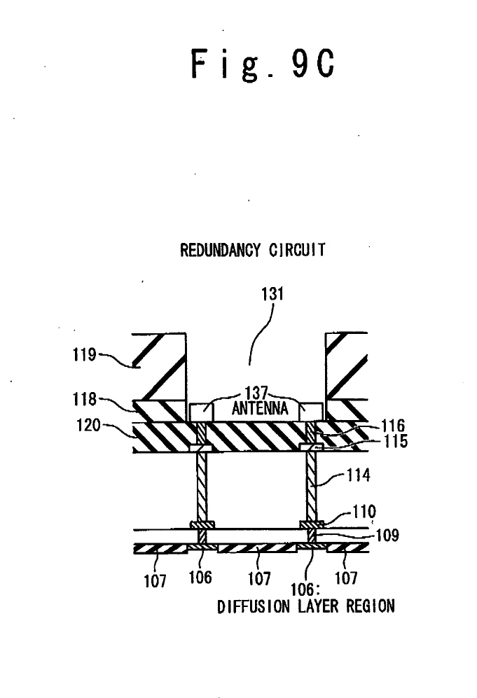

If a defective bit is present in the memory cell region 51, a corresponding fuse in the redundancy circuit 52 is cut so that the word line 61 or the bit line 60 connected to the defective bit of the memory cell region 51 is replaced with a redundant line. Thus, a proper operation is achieved. FIG. 7 is a plan view schematically showing the structure of a portion of the semiconductor device with a fuse section 10 in the redundancy circuit according to the first embodiment of the present invention. As shown in FIG. 7, in the semiconductor device according to the present embodiment, a fuse window 12 is opened to ensure the cutting margin of each of fuses of the fuse section 10, by removing a protection film laminated on the fuse section 10. Then, the fuse in the fuse section 10 is connected to the redundancy circuit region 14 through the connecting layer 11. FIGS. 8A to BC show cross sectional views of a region corresponding to a cut fuse of the fuse section along the line C-C′ shown in FIG. 7, and FIGS. 9A to 9C show cross sectional views of a region, where no fuse is arranged, corresponding to a portion along the line D-D′ shown in FIG. 7.

FIGS. 8A to 8C show cross sections including a memory cell (FIG. 8A), a peripheral circuit (FIG. 8B), and a redundancy circuit (FIG. 8C), which are all formed on the same substrate. The memory cell (FIG. 8A) and the peripheral circuit (FIG. 8B) are shown in correspondence with the redundancy circuit (FIG. 8C). A description will be given on the configuration of the redundancy circuit (FIG. 8C) having a redundant function. In the redundancy circuit, groove-type separation regions 107 and diffusion layers 106 are formed in a surface portion of a silicon substrate. The diffusion layers 106 on the both sides of the groove-type separation region 107 correspond to the connecting layer 11 in FIG. 7, and the diffusion layers 106 provided for the gate electrode 108 and a region adjacent to the gate electrode 108 correspond to the redundancy control circuit region 14 in FIG. 7. For example, a bit line 110 of tungsten in the memory cell region is formed in a first wiring layer 110 in the peripheral circuit and the redundancy circuit and connected to the diffusion layer 106 through a plug 109. In the memory cell shown in FIG. 8A, a storage capacitor is composed of a lower electrode 111, an insulating film 112, and an upper electrode 113, and is connected to the diffusion layer-region 106 through a plug 105. A second wiring layer 115 is formed of aluminum and connected to the first wiring layer 110 by plugs 114 through an insulating film such as an interlayer insulating film. The third wiring layer 117 is formed of aluminum and connected to the second wiring layer 115 by plugs 116 through an interlayer insulating film. A protection film composed of a nitride film 118 and a polyimide film 119 is formed on the third wiring layer 117. On the other hand, in the redundancy circuit according to the present embodiment shown in FIG. 8C, a fuse 132 is formed in the same layer as the second wiring layer 115, and is connected to diffusion layers 106 by the plugs 114, the first wirings 110, and the plugs 109. The fuse 132 shown in FIG. 8C is cut with laser, and the interlayer insulating film 120 on the fuse 132 is vaporized with heat generated upon laser irradiation. Thus, a fuse exposing section 133 is formed. The cut portion of the fuse 132 is partially exposed to the outside.

The present embodiment further includes antenna films of an antenna section 15 which is formed in the same layer as the third wiring layer 117. The antenna section 15 is divided into two antenna films 15 (see FIG. 7), each of which is formed linearly along the ends of the fuses on one side. The antenna section 15 is connected through the plugs 116, the second wiring layer 115, the plugs 114, the first wiring layer 110, and the plugs 109 to the diffusion layers 106 separated from the internal circuit, as shown in FIG. 9C. Moreover, as shown in FIG. 8C, in the present embodiment, the region of the protection film 118 and 119 including the fuse 132 and the antenna films 137 of the redundancy circuit is removed to form the fuse window 131, whereby the antenna films 137 are formed in such a manner as to be partially exposed in the fuse window 131.

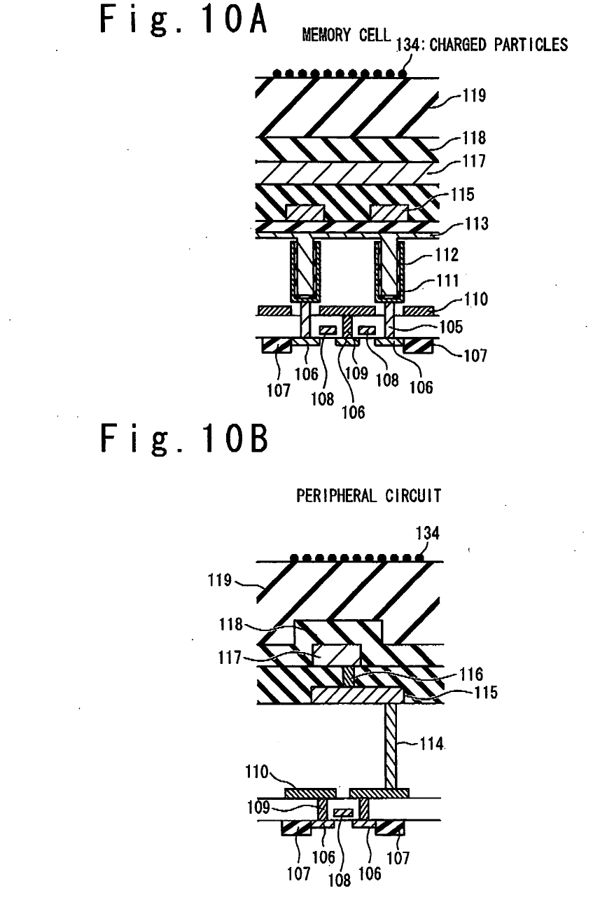

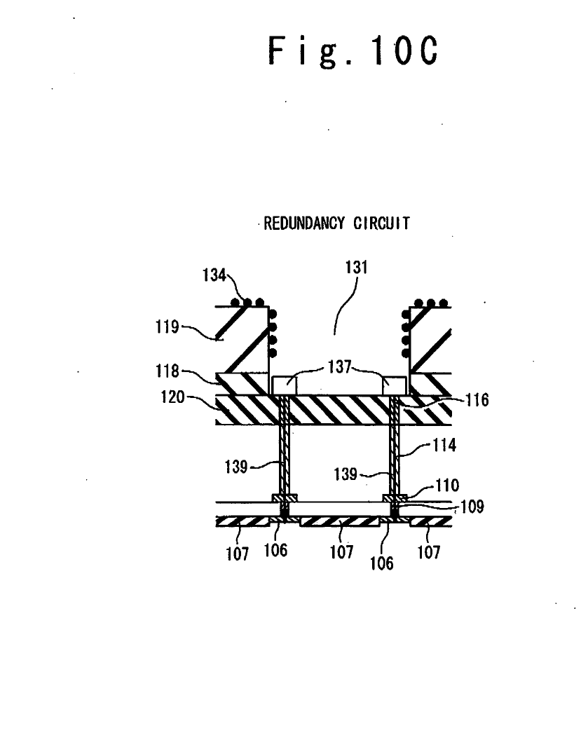

FIGS. 10A to 10C are cross sectional views schematically showing the charged states of the redundancy circuit, the memory cell, and the peripheral circuit, in the semiconductor device with of the present embodiment, respectively. In the semiconductor device of the present invention (FIG. 10C), a discharge route 139 for the charged particles 134 adhering onto the surface is formed of the antenna film 137, the plug 116, the second layer 115, the plug 114, the first wiring layer 110, the plug 109, and the diffusion layer 106 separated from the internal circuit. As a result, the charges of the particles are passed to the diffusion layer 106 through the antenna film 137 formed above the fuse section to the substrate without flowing into the fuse section through the fuse window 131 and the fuse exposing section 133. Therefore, it is not necessary to completely surround the fuse section 10 and a highly reliable semiconductor device is realized by preventing the breakdown in the device which is conventionally caused by the penetration of charged particles through the fuse section.

The antenna film 137 in the present embodiment has a role in discharging charge on the protection film to the substrate. Also, the antenna film 137 has a role as a guard ring provided for the purpose of ensuring the humidity resistance and prevention of contamination from the outside. However, the antenna films 137 included in the semiconductor device of the present invention do not necessarily have to be arranged to surround the fuse section 10 as in the guard ring, as long as the exposed portion of the antenna films 137 in the fuse window 12 is electrically connected to the substrate. Thus, the antenna films 137 can be arranged as appropriate in any manner in accordance with the size of the fuse window 12, usage environment, and the like in the semiconductor device.

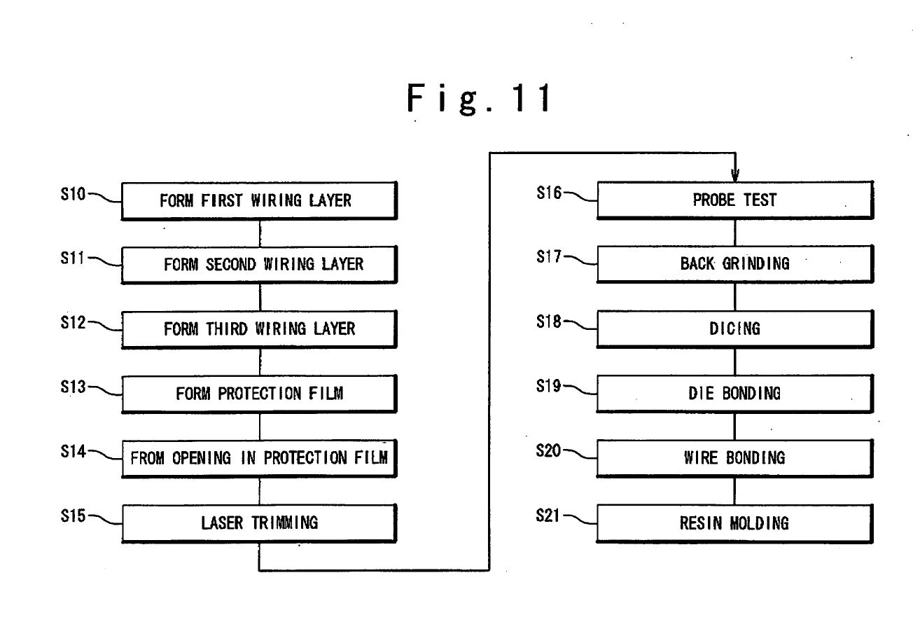

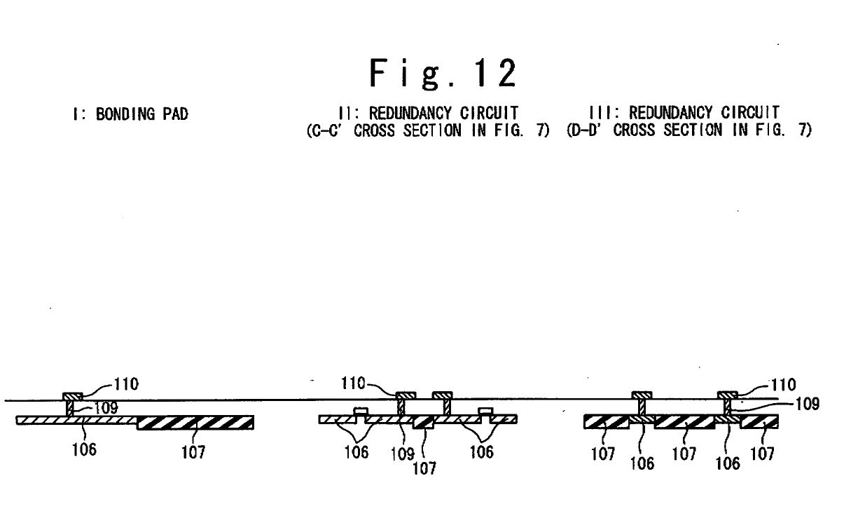

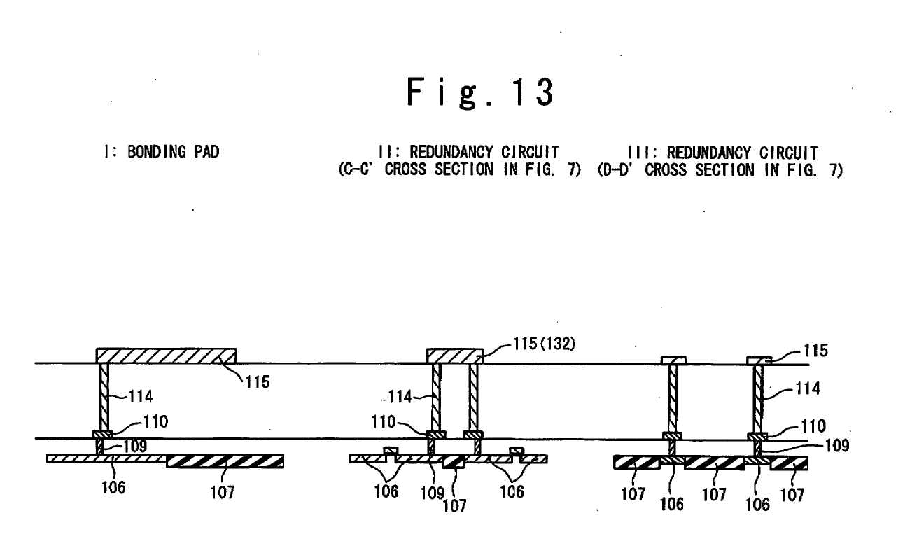

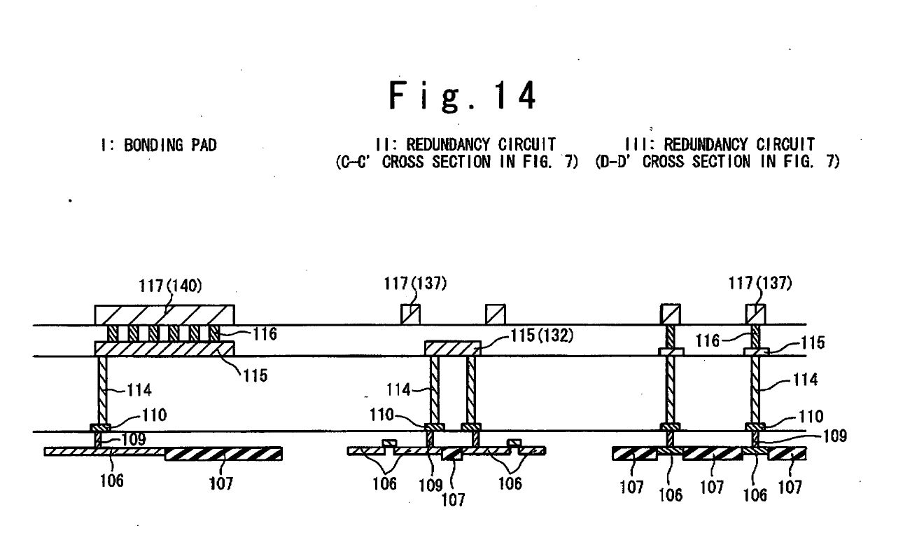

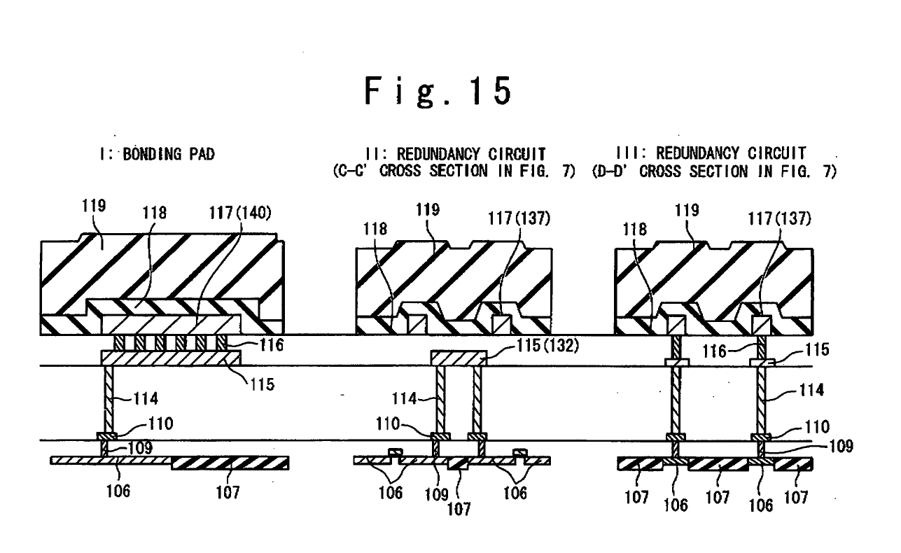

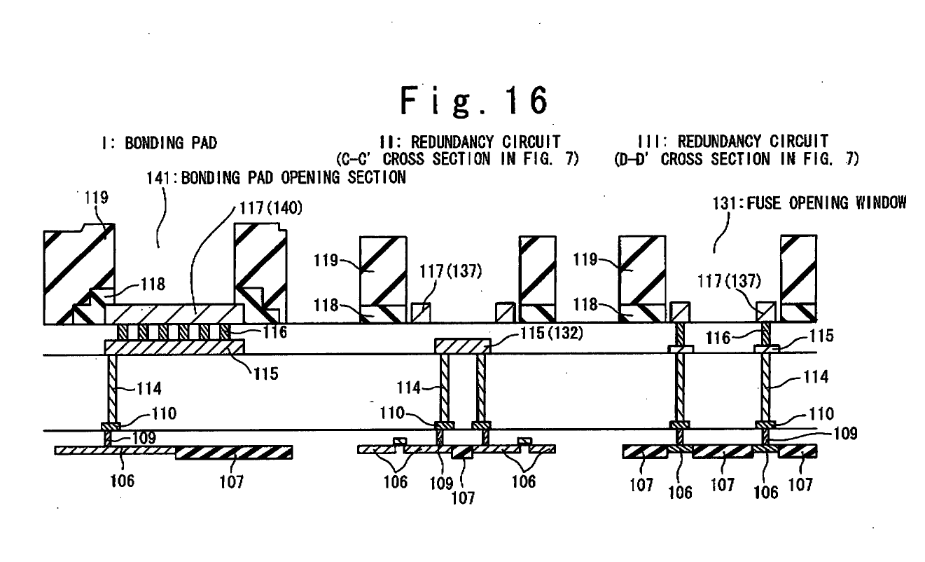

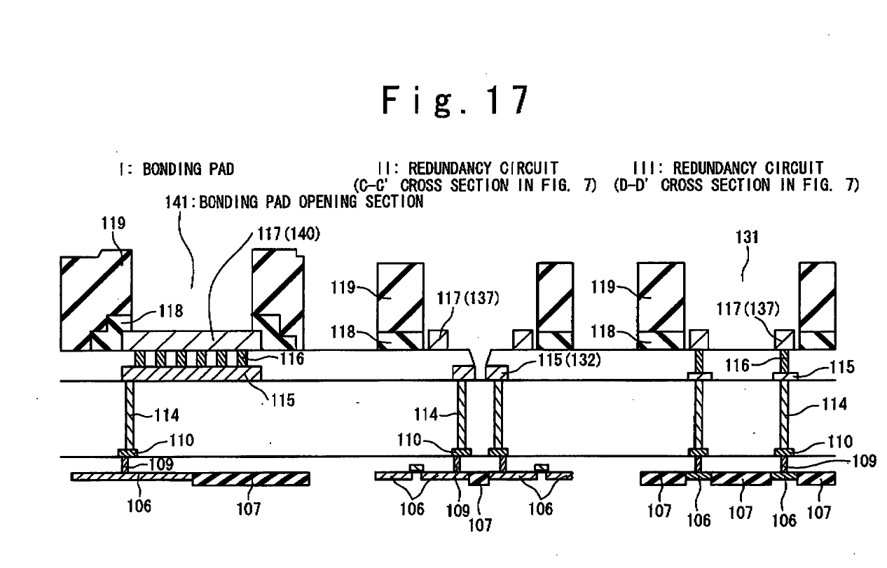

Next, a method of manufacturing a semiconductor device according to the present invention will be described. FIG. 11 is a diagram schematically showing a manufacturing process of the semiconductor device according to the first embodiment of the present invention. The manufacturing process of the semiconductor device according to the present embodiment includes: a formation of the first wiring layer above the substrate where the diffusion layers are formed (step S10), a formation of the second wiring layer (step S11), a formation of the third wiring layer (step S12), a formation of the protection film (step S13), the opening of the protection film (step S14), the laser trimming (step S15), the probe test (step S16), the back grinding (step S17), the dicing (step S18), the die bonding (step S19), the wire bonding (step S20), and the resin molding (step S20). FIGS. 12 to 17 show cross sectional views of the semiconductor device corresponding to the steps S10 to S15 and including a bonding pad section and a redundancy circuit with fuses. The above-mentioned manufacturing process (steps S10 to 21) is based on the standard manufacturing processes, and thus omitted from the description here.

In the manufacturing method of the semiconductor device according to the present embodiment, in the process shown in FIG. 14 (step S12), optimum antenna films 137 are formed in a same layer as the third wiring layer 117 as appropriate. At the same time, the bonding pad section 140 is formed. In the process shown in FIG. 16 (step S14), a bonding pad opening section 141 for a bonding pad 140 and the fuse window 131 are formed at the same time. Thus, the manufacturing method of the semiconductor device according to the present embodiment does not require a new process for forming the antenna films 137. In the manufacturing processes according to the manufacturing method of the present embodiment, while the state at which the cut section of the fuse 132 is partially exposed in the fuse window 131, is maintained from the laser trimming (step S15) to the end of resin molding (step S21) while the charge breakdown of the semiconductor device is possibly caused in the state. As mentioned above, in the semiconductor device according to the present embodiment, the charged particles adhering onto the surface as a result of charging are quickly discharged to the substrate through the antenna films 137.

### Second Embodiment

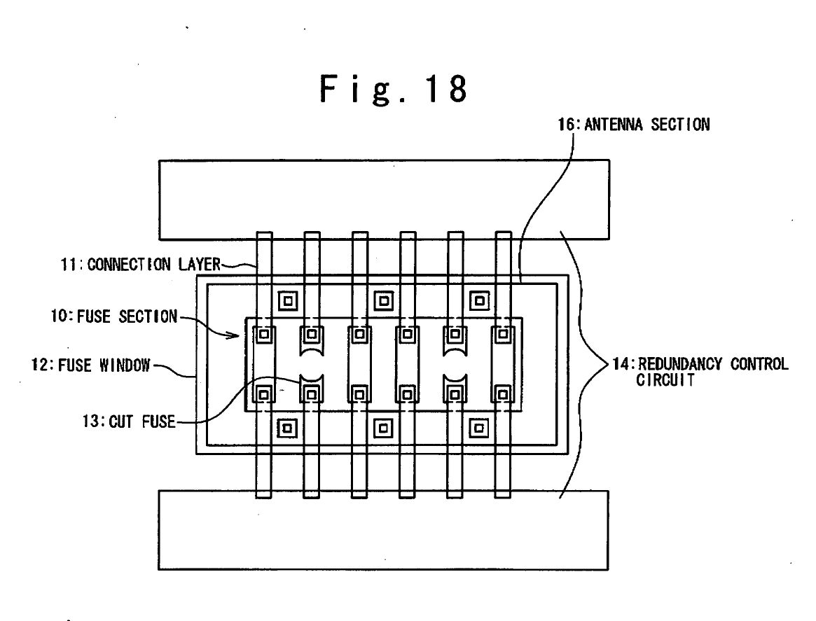

FIG. 18 is a plan view schematically showing the configuration of the semiconductor device according to the second embodiment of the present invention. Basic components of the semiconductor device and a manufacturing method thereof in the present embodiment are same as those in the first embodiment. However, an antenna section 16 formed in the same layer as the third wiring layer in the present embodiment is different from that in the first embodiment. The antenna section 16 in the present embodiment is arranged along the wall surface of the fuse window 12 in the form of the ring.

In the present embodiment, the annular antenna section 16 shown in FIG. 18 is provided to be at least partially exposed in the fuse window 12, forms the discharge route of the charges of the charged particles adhering onto the surface, as in the first embodiment. As a result, the charges are discharged to the substrate. Therefore, the highly reliable semiconductor device is achieved by preventing the charge breakdown in the device conventionally caused by the penetration of charges through the fuse. Moreover, in the present embodiment, the antenna section 18 has a function as the guard ring to completely surround the fuse section, thereby improvement in the reliability related to this function is achieved.

### Third Embodiment

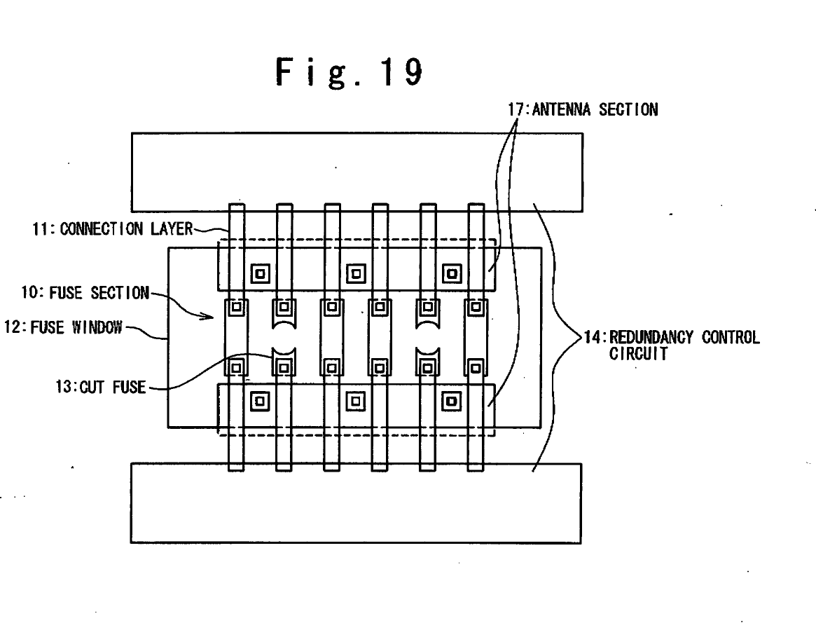

FIG. 19 is a plan view schematically showing the configuration of a semiconductor device according to the third embodiment of the present invention. Basic components and a manufacturing method thereof of the present embodiment are the same as those in the first embodiment. However, the antenna section 17 formed in the same layer as the third wiring layer in the present embodiment is different from that in the first embodiment. The antenna section 17 in the present embodiments is provided with: an antenna film linearly arranged along the ends of fuses on one side to be at least partially exposed in the fuse window 12; and an antenna film linearly arranged along the ends of the fuses on the other side to be at least partially exposed in the fuse window 12. In the present embodiment, the annular antenna section 17 shown in FIG. 19 is composed of the two antenna films, which are at least partially exposed in the fuse window 12 formed by removing the protection film laminated on the fuse section 10, as in the first embodiment. As a result, the charged particles are introduced into the antenna section 17 and then discharged to the substrate, without passing into the fuse section. Therefore, the highly reliable semiconductor device is achieved by preventing the charge breakdown in this device conventionally caused by the penetration of charged particles through the fuse cut part. Moreover, in the present embodiment, the antenna section may be covered by the fuse window 12, thereby the semiconductor device having a higher charge breakdown prevention function than the semiconductor device of the first embodiment is achieved.

### Fourth Embodiment

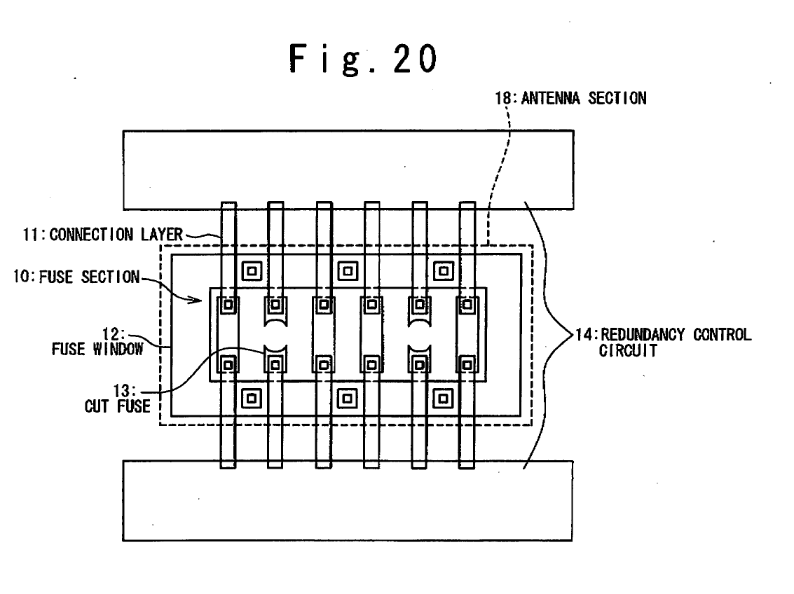

FIG. 20 is a plan view schematically showing a configuration of the semiconductor device according to a fourth embodiment of the present invention. The present embodiment has components of the second and third embodiments. A manufacturing method of the present embodiment is the same as that in the first embodiment. As shown in FIG. 20, the antenna section 18 in the present embodiment has a configuration such that a partial region of the antenna section 18 (FIG. 18) shaped into the form of the ring in the second embodiment is covered with the protection film, as the antenna section 17 (FIG. 19) shown in the third embodiment. In the present embodiment, the antenna section 18 shown in FIG. 20 is at least partially exposed in the fuse window 12 formed by removing the protection film laminated on the fuse section, as in the first to third embodiments. As a result, the charged particles generated by charging are introduced into the antenna section 18 and then discharged to the substrate, without passing into the fuse section. Therefore, the highly reliable semiconductor device is achieved by preventing the charge breakdown in the device conventionally caused by the penetration of charged particles through the fuse cut part.

### Fifth Embodiment

A semiconductor memory according to a fifth embodiment of the present invention is provided with: the memory cell region; any one of the semiconductor devices described in the first to fourth embodiments as the redundancy circuit for performing redundancy control of the memory cell region; an I/O as an input and output parts between the memory and an external device; and a peripheral circuit for performing interface control between the memory and the external device (see FIG. 6 for the schematic configuration of the semiconductor memory). The memory cell region, the redundancy circuit described in any of the first to fourth embodiments, the I/O, and the peripheral circuit are integrally formed on the same substrate. In the memory cell region, to a word line, a row decoder driver and a row address buffer are serially connected. To a bit line of the memory cell region, a sense amplifier, a column decoder driver, and a column address buffer are serially connected.

In the present embodiment, when the memory cell region is defective, the redundancy circuit described in any of the first to fourth embodiments is cut to thereby replace the word line or the bit line connected to the defective bit of the memory cell region with the redundant line, thereby achieving proper operation.

In the present embodiment, the redundancy circuit in the first to fourth embodiments is provided, so that the surface of the semiconductor memory absorbs moisture, which prevents the charge breakdown of the semiconductor memory conventionally caused by the penetration of charged particles through the fuse section after switching to the redundancy system, and achieves a highly reliable semiconductor memory.

It should be noted that the above description is given by exemplifying the DRAM. However, the present invention is not limited to the DRAM. The present invention is applicable to other types of memory devices such as an SRAM and a flash memory. Also, the present invention is applicable to another semiconductor device which does not have a fuse.

What is claimed is:

1. A semiconductor device comprising:
a semiconductor substrate having a diffusion layer;
an insulating film formed on said semiconductor substrate;
a fuse section of fuses formed on said insulating film;
an interlayer insulating film formed on said fuse section and said insulating film; and
an antenna section formed on said interlayer insulating film in correspondence to said fuse section.

2. The semiconductor device according to claim 1, further comprising:
a contact plug configured to connect said antenna section and said diffusion layer.

3. The semiconductor device according to claim 2, further comprising:
a protection layer formed on said antenna section and said interlayer insulating film; and
a fuse window formed by removing a portion of said protection layer in correspondence to said fuse section to allow a fuse to be cut.

4. The semiconductor device according to claim 3, wherein said antenna section is arranged such that at least a portion of said antenna section is exposed in said fuse window.

5. The semiconductor device according to claim 2, wherein said antenna section comprises two sections,
one of said two sections is arranged along one end of each of fuses of said fuse section, and
the other is arranged along the other end of each fuse.

6. The semiconductor device according to claim 2, wherein said antenna section has a ring shape to surround said fuse section.

7. The semiconductor device according to claim 2, wherein said fuse window is formed such that at least a port of said antenna section is exposed.

8. The semiconductor device according to claim 2, wherein said fuse window is formed such that a whole of said antenna section is exposed.

9. A semiconductor memory device comprising:
a semiconductor substrate having a diffusion layer of diffusion regions;
a memory cell region formed on said semiconductor substrate;
a device region formed on said semiconductor substrate; and
an input/output circuit region formed on said semiconductor substrate to input and output data,
wherein said device region comprises:
an insulating film formed directly or indirectly on said semiconductor substrate;
a fuse section of fuses formed on said insulating film;
an interlayer insulating film formed on said fuse section and said insulating film;
an antenna section formed in said interlayer insulating film in correspondence to said fuse section; and
a contact connected to said antenna section and said diffusion layer.

10. A method of manufacturing a semiconductor device, comprising:
forming an insulating film above said semiconductor substrate;
forming a fuse section having fuses on said insulating film;
forming an interlayer insulating film on said fuse section and said insulating film; and
forming an antenna section on said interlayer insulating film in correspondence to said fuse section.

11. The method according to claim 10, wherein said antenna section comprises two sections, and
said forming an antenna section comprises:
forming one of said two sections along one end of each of said fuses of said fuse section, and the other along the other end of each fuse.

12. The method according to claim 10, wherein said forming an antenna section comprises:
forming said antenna section of a ring shape to surround said fuse section.

13. The method according to claim 10, further comprising:
forming a protection layer on said antenna section and said interlayer insulating film.

14. The method according to claim 11, further comprising:
forming a fuse window which comprises:
removing a portion of said protection layer such that at least a portion of said antenna section is exposed; and
removing at least a portion of said interlayer insulating film such that at least a portion of said fuses is exposed.

15. The method according to claim 14, wherein said removing a portion of said protection layer comprises:
removing said interlayer insulating film such that a whole of said antenna section is exposed.
